(19) United States
(12) Patent Application Publication
(10) Pub. No.: US 2024/0363317 A1
(43) Pub. Date: Oct. 31, 2024

(54) METHOD OF PLASMA CLEANING OF FUSED SILICA TUBES

(71) Applicant: Applied Materials, Inc., Santa Clara, CA (US)

(72) Inventors: Vicknesh Sahmuganathan, Singapore (SG); Sze Chieh Tan, Singapore (SG); Kok Keong Lim, Singapore (SG); Song Seng Low, Singapore (SG); Yi Kun Kelvin Goh, Singapore (SG); Abdul Rahman Bin Abu Bakar, Singapore (SG); Syed Muhammad Darwis, Singapore (SG); Cheng Hong Tan, Singapore (SG); John Sudijono, Singapore (SG); Han Yan Koh, Singapore (SG)

(73) Assignee: Applied Materials, Inc., Santa Clara, CA (US)

(21) Appl. No.: 18/138,811

(22) Filed: Apr. 25, 2023

(51) Int. Cl. H01J 37/32; C23C 16/511; C23C 16/56; H01L 21/02

(52) U.S. Cl. CPC H01J 37/32862; C23C 16/511; C23C 16/56; H01J 37/3222; H01J 37/32229; H01J 37/32816; H01L 21/02274; H01J 2237/332

(57) ABSTRACT

Methods and apparatus for cleaning a dielectric tube are described. The dielectric tube is exposed to a cleaning gas comprising a fluorine-containing compound and a microwave plasma is generated. The dielectric tube is cleaned to restore transparency and increase electronic coupling between the microwave waveguide and the plasma through the dielectric tube.

### TECHNICAL FIELD

Embodiments of the present disclosure generally relate to methods for forming cleaning dielectric tubes, also referred to as microwave plasma tubes. In particular, embodiments of the disclosure relate to methods for cleaning fused silica tubes using a microwave plasma.

### BACKGROUND

Plasma-enhanced deposition processes are common in the semiconductor manufacturing process. Both direct and remote plasmas generated by various ignition sources are used. In microwave plasma processing chambers, microwave energy is applied to a waveguide (also called an antenna or electrode), which couples to a gas in the processing chamber, causing the ignition of the gas into a plasma.

The microwave plasma waveguide is often positioned within a dielectric material (e.g., a fused silica tube) to separate the antenna from the plasma. During plasma deposition processes, a film is formed on the dielectric material, causing a decrease in the efficiency of the electronic coupling between the antenna and the plasma. The presence of this film decreases the effective lifetime of the plasma tube. This results in a need to replace the tube frequently, increasing the cost-of-ownership of the tool and processing chamber down-time.

Accordingly, there is a need for methods of cleaning dielectric tubes to increase the effective lifetime of the tube.

### SUMMARY

One or more embodiments of the disclosure are directed to a method of cleaning a dielectric tube, the method including: exposing the dielectric tube to a cleaning gas including a fluorine-containing compound; and generating a microwave plasma from the cleaning gas to clean the dielectric tube.

Additional embodiments of the disclosure relate to a method of depositing a film in a microwave plasma processing chamber, the method including: depositing a film comprising carbon, boron, nitride or oxide on a substrate surface by exposing the substrate surface to a microwave plasma in the microwave plasma processing chamber, the microwave plasma generated using a microwave waveguide positioned within a dielectric tube, the film depositing on the substrate surface and the dielectric tube; and cleaning the dielectric tube by exposing the dielectric tube to a cleaning microwave plasma of a cleaning gas, the cleaning gas including a fluorine-containing compound.

Further embodiments of the disclosure are directed to a microwave plasma processing chamber including: at least one microwave plasma source including a microwave antenna within a dielectric tube including fused silica; and a controller connected to the microwave plasma processing chamber, the controller having a configuration to deposit a film on a substrate surface within the microwave plasma processing chamber, and a configuration to clean the dielectric tube within the microwave plasma processing chamber, wherein cleaning the microwave plasma includes exposing the dielectric tube to a cleaning microwave plasma of a cleaning gas, the cleaning gas including a fluorine-containing compound.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic diagram of a plasma processing tool that includes a microwave plasma source according to one or more embodiment of the disclosure; and

FIG. 2 illustrates an exemplary process sequence for cleaning a dielectric tube according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

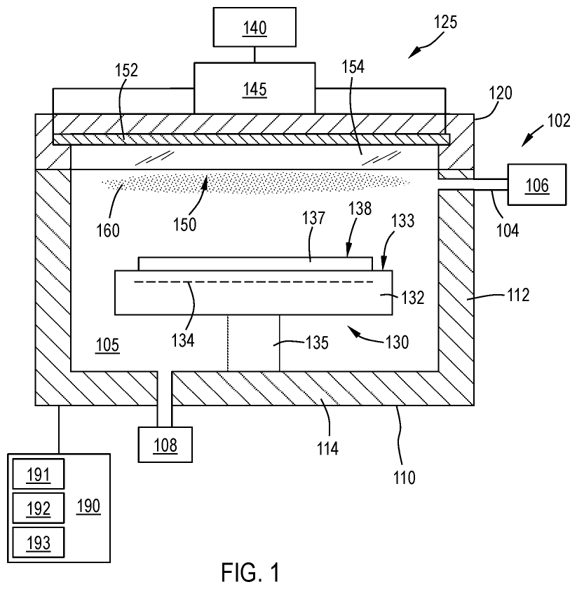

Embodiments of the present disclosure relate to apparatus and methods of cleaning a dielectric tube. FIG. 1 illustrates a microwave system 100 with a water-cooled vacuum chamber (process chamber 110) with a lid 120. The process chamber 110 has a sidewall 112 and a bottom 114 enclosing a processing volume 105. The processing chamber 110 includes a process gas distribution system 102 and a substrate support 130.

The process gas distribution system 102 illustrated in FIG. 1 shows a gas line 104 extending between the gas source 106 and the process volume 105. The skilled artisan will recognize that this is merely one type of gas distribution system 102 that can be used with the embodiments of the disclosure. In some embodiments, the process gas distribution system 102 comprises a showerhead to provide a gas flow into the process volume 105.

The substrate support 130 comprises a substrate stage 132 having a support surface 133. The illustrated embodiment shows a substrate 137 with a substrate surface 138 on the support surface 133 of the substrate stage 132. The substrate stage 132 includes a heater 134 embedded within the body of the substrate stage 132. The substrate stage 132 is positioned on a support post 135. The support post 135 of some embodiments is configured to move the substrate stage 132 closer to and further from the lid 120 and to rotate the substrate stage 132 around a central axis of the support post 135. The skilled artisan will be familiar with the hardware associated with rotational and translational movement of the substrate stage 132. In some embodiments, the substrate stage 132 includes an electrostatic chuck, as will be understood by the skilled artisan. The substrate stage 132 of some embodiments may also include cooling lines and/or a heater 134 to provide temperature control to the substrate 137 during processing.

In some embodiments, the process chamber 110 has a vacuum source 108 coupled to the process volume 105. The vacuum source 108 can be any suitable source known to the skilled artisan that can reduce the pressure within the process volume 105 and evacuate gases used during processing.

The lid 120 includes a planar microwave plasma source 125. The planar microwave plasma source 125 is broken up into the microwave generator 140 and a microwave magnetron head 145. In some embodiments the microwave generator 140 operates at a frequency of 2.45 GHz either in continuous wave (CW) mode or pulsed mode.

During operation, microwave energy is delivered from the microwave heads 145 to one or more coaxial antenna 150 via a rectangular waveguide 152. The one or more coaxial antenna 150 is a coaxial plasma line that basically operates as a coaxial transmission line. The inner conductor is the rectangular waveguide 152 and the outer conductor is the conductive plasma discharge 160 which forms at the outer surface of a dielectric tube 154. The dielectric tube 154 acts as a vacuum-to-atmosphere interface for the microwaves.

The dielectric tube 154 can be made of any suitable dielectric material. In some embodiments the dielectric tube 154 comprises a clear material which has a low dielectric loss tangent. In some embodiments, the dielectric tube 154 comprises fused silica. The transparency of the dielectric tube 154 (e.g., a fused silica tube) allows the coupling of power between the rectangular waveguide 152 and the conductive plasma discharge 160 to ignite the gas within the process volume 105.

As a result of the plasma chemistry (i.e., the composition of the gas in the process volume 105), the dielectric tube 154 become coated. Over time, a thicker coating on the dielectric tube 154 decreases the electronic coupling between the rectangular waveguide 152 and the conductive plasma discharge 160, preventing power from being delivered to the plasma 160 and causing undesirable issues, such as low deposition rate and low-quality films being deposited on the substrate surface 138.

Some embodiments of the disclosure advantageously provide methods for cleaning the dielectric tube 154 without removal from the process volume 105. Some embodiments advantageously remove the coating formed on the outside of the dielectric tube 154, allowing transparency to return, increasing the electronic coupling between the rectangular waveguide 152 and the plasma 160. The inventors have observed that existing cleaning and/or etching processes can result in either carbon residues or boron residues, depending on the type of plasma chemistry used, which foul the outside of the dielectric tube 154. Some embodiments of the disclosure advantageously provide methods for removing carbon residue or boron residue from the outside surface of the dielectric tube 154. Some embodiments advantageously provide methods of cleaning fused silica tubes to remove residue using fluorine-based chemistry.

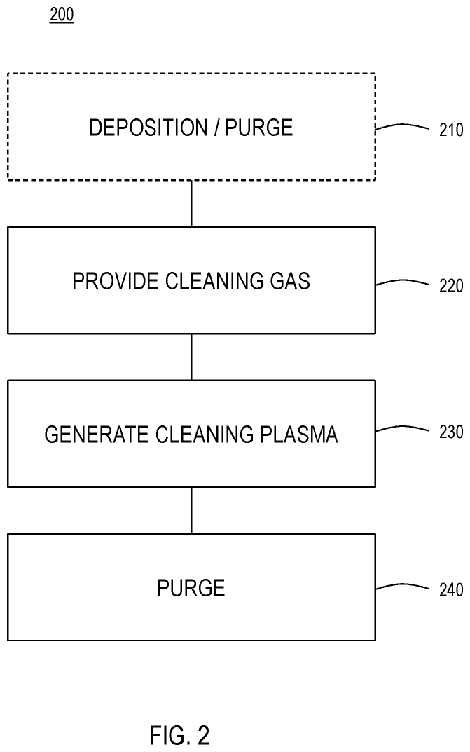

FIG. 2 illustrates a method 200 of cleaning a dielectric tube 154. The method 200 begins with optional operation 210 in which a film is deposited on a substrate surface. The film is deposited by exposing the substrate surface to a microwave plasma in the microwave plasma processing chamber. The film deposits on the surface of the dielectric tube 154. After deposition, the process volume 105 of the process chamber 110 is purged to remove unreacted species. In some embodiments, the deposition process uses diborane (B₂H₆), nitrogen (N₂) and/or hydrogen (H₂) The deposition process of some embodiments results in the formation of silicon carbide (SiC) or silicon boride (Si₃B₄) on the surface of the dielectric tube 154. After deposition, still as part of optional operation 210, the process volume 105 is purged of unreacted deposition gases, including reaction products and by-products.

Additionally, as part of optional operation 210, the substrate 137 may be removed from the microwave chamber 100 prior to cleaning the dielectric tube 154. In some embodiments, the substrate 137 remains in the microwave chamber 100 while cleaning the dielectric tube 154. The substrate 137 can be removed from the microwave chamber 100 by any suitable technique known to the skilled artisan. For example, a robot can be used to remove the substrate 137 from the process volume 105 through a slit valve (not shown) in the sidewall 112 of the process chamber 110.

At operation 220, a cleaning gas is flowed into the process volume 105. The cleaning gas of some embodiments comprises a fluorine-containing compound. In some embodiments, the cleaning gas further comprises a noble gas or molecular nitrogen (N₂). In some embodiments, the noble gas comprises one or more of helium, neon, argon or krypton. In some embodiments, the noble gas in the cleaning gas comprises or consists essentially of argon. As used in this manner, the term “consists essentially of” means that the stated noble gas in the cleaning gas is greater than or equal to 95%, 98%, 99% or 99.5% of the total noble gas composition, including molecular nitrogen, of the cleaning gas. The fluorine-containing compound is not taken into consideration in this calculation. As used in this manner, the term “noble gas” includes molecular nitrogen, unless otherwise specified.

The ratio of the fluorine-containing compound and the noble gas or molecular nitrogen may affect the overall cleaning of the dielectric tube 154. In some embodiments, the fluorine-containing compound and noble gas or molecular nitrogen are in a ratio in the range of 1:1 to 1:10, or in the range of 1:1 to 1:4. In some embodiments, the fluorine-containing compound and noble gas (or molecular nitrogen) are in a composition that is less than or equal to 75%, 50%, 40%, 35%, 30%, 25%, 20%, 15% or 10% fluorine-containing compound, on a molar basis.

The fluorine-containing compound can be any suitable fluoride species. In some embodiments, the fluorine-containing compound comprises one or more of carbon tetrafluoride (CF₄), nitrogen trifluoride (NF₃) or sulfur hexafluoride (SF₆). In some embodiments, the fluorine-containing compound comprises carbon tetrafluoride (CF₄). In some embodiments, the fluorine-containing compound consists essentially of carbon tetrafluoride (CF₄). As used in this manner, the term “consists essentially of” means that the stated fluorine-containing compound in the cleaning gas is greater than or equal to 95%, 98%, 99% or 99.5% of the total fluorine-containing compound. The noble gas or molecular nitrogen component of the cleaning gas is not considered in this calculation. In some embodiments, the fluorine-containing compound comprises nitrogen trifluoride (NF₃). In some embodiments, the fluorine-containing compound consists essentially of nitrogen trifluoride (NF₃). In some embodiments, the fluorine-containing compound comprises sulfur hexafluoride (SF₆). In some embodiments, the fluorine-containing compound consists essentially of sulfur hexafluoride (SF₆).

At operation 230, a microwave plasma is generated from the cleaning gas to clean the dielectric tube 154. In some embodiments, the microwave plasma is a continuous wave plasma. In some embodiments, the microwave plasma is a pulsed plasma.

In some embodiments, the microwave plasma has a power in the range of 2 kW to 12 kW. In some embodiments, the microwave plasma is a continuous wave plasma with a power in the range of 2 kW to 12 kW, or in the range of 3 kW to 11 kW, or in the range of 4 kW to 10 kW, or in the range of 5 kW to 9 kW.

In some embodiments, the cleaning gas is at a pressure in the range of 0.1 Torr to 10 Torr. In some embodiments, the microwave plasma is a continuous plasma and the cleaning gas is flowed into the process volume 105 of the process chamber at a pressure in the range of 1 mTorr to 100 Torr, or in the range of 10 mTorr to 50 Torr, or in the range of 100 mTorr to 10 Torr.

In some embodiments, the dielectric tube is maintained at a temperature in the range of room temperature to 300° C. As used in this manner, “room temperature” is 25° C. In some embodiments, the dielectric tube 154 is maintained at a temperature in the range of 50° C. to 250° C., or in the range of 100° C. to 200° C. In some embodiments, the dielectric tube 154 is maintained at a temperature less than 200° C., 150° C., 100° C. or 50° C., and greater or equal to room temperature.

In some embodiments, the dielectric tube 154 is removed from the deposition chamber and cleaned in a separate cleaning chamber. Some embodiments advantageously allow for the deposition and cleaning processes to occur in the same process chamber. In some embodiments, the dielectric tube is cleaned in the same chamber as is used for plasma deposition processing resulting in the need for cleaning the dielectric tube, without removing the tube from a process position.

The dielectric tube 154 can be made of any suitable material known to the skilled artisan. In some embodiments, the dielectric tube 154 comprises one or more of aluminum oxide, silicon nitride, quarts or fused silica.

The method described herein has been found to substantially increase the lifetime of the dielectric tube. In some embodiments, the cleaned dielectric tube has at least double the lifetime of an uncleaned dielectric tube.

Additional embodiments are directed to methods of depositing a film in a microwave plasma processing chamber. In some embodiments, the film comprises one or more of carbon, boron, nitride or oxide. After a predetermined deposition time, the dielectric tube in the plasma processing chamber is cleaned by exposing the dielectric tube to a cleaning microwave plasma of a cleaning gas. The microwave plasma is generated using a microwave waveguide positioned within a dielectric tube where a film forms on the substrate surface and the dielectric tube. In some embodiments, the film formed on the substrate surface is different than the material deposited on the dielectric tube.

In some embodiments the microwave plasma processing chamber comprises one microwave waveguide within a dielectric tube. In some embodiments, the microwave plasma processing chamber comprises more than one microwave waveguide, each of the waveguides positioned within a dielectric tube.

Referring back to FIG. 1, some embodiments of the disclosure are directed to microwave plasma processing chambers. The microwave plasma processing chamber 100 comprises at least one microwave plasma source 125. The planar microwave plasma source 125 comprises a rectangular waveguide 152 positioned within a dielectric tube 154.

The rectangular waveguide 152, also referred to as an antenna or powered electrode, can be any suitable material known to the skilled artisan. In some embodiments, the rectangular waveguide 152 comprises one or more of tungsten (W), molybdenum (Mo), or tantalum (Ta). In some embodiments, the rectangular waveguide 152 consists essentially of tungsten. As used in this manner, the term “consists essentially of” means that the rectangular waveguide 152 is greater than or equal to about 95%, 98% or 99% of the stated material, on an atomic basis. In some embodiments, the powered electrode 350 comprises, consists essentially of, or consists of molybdenum. In some embodiments, the powered electrode 350 comprises, consists essentially of, or consists of tantalum.

The width of the rectangular waveguide 152 can be any suitable width. The width of the dielectric tube 154 can be based on the width of the rectangular waveguide 152 or independent of the width of the rectangular waveguide 152 so long as the dielectric tube 154 width is sufficient to enclose the rectangular waveguide 152. In some embodiments, the rectangular waveguide 152 has a width in the range of about 2 mm to about 50 mm, or in the range of about 4 mm to about 40 mm, or in the range of about 5 mm to about 30 mm, or in the range of about 7 mm to about 20 mm, or in the range of about 8 mm to about 15 mm. In some embodiments, the width of the rectangular waveguide 152 is about 10 mm.

In some embodiments, the width of the rectangular waveguide 152 changes from the first end to the second end of the rectangular waveguide 152. In embodiments of this sort, the width of the dielectric tube 154 can vary with the width of the rectangular waveguide 152 or can be a fixed width from the first end to the second end of the dielectric tube 154.

In some embodiments, the dielectric tube 154 is sized to provide a gap between the rectangular waveguide 152 and the dielectric tube 154. In some embodiments, the gap is sufficient to separate the rectangular waveguide 152 from the dielectric tube 154 to prevent direct electrical contact therebetween. In some embodiments, the dielectric tube 154 and rectangular waveguide 152 have a gap in the range of 0.5 mm to 50 mm, or in the range of 0.75 mm to 25 mm, or in the range of 1 mm to 20 mm.

In some embodiments, as shown in FIG. 1, a controller 190 is coupled to one or more of the system 100, microwave magnetron head 145, microwave generator 140, support post 135, substrate support 130, or planar microwave plasma source 125 for controlling the system 100 or components thereof. For example, the system controller 190 may control the operation of the system 100, actuators, valves, flow controllers, power supplies, etc., and any monitoring components known to the skilled artisan that are included in the system. In operation, the system controller 190 may enable data collection and feedback from the system 100 and/or planar microwave plasma source 125 to coordinate system performance.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers or valves to perform processes in accordance with the various methods.

In some embodiments, the control 190 has one or more predetermined configurations for controlling components of the system 100. In some embodiments, the control 190 has one or more configurations to deposit a film on a substrate surface within the system 100, and one or more configurations to clean the dielectric tube 154 within the process chamber 110. In some embodiments, cleaning the dielectric tube 154 comprises one or more configurations to provide a gas flow of a cleaning gas, supply power to a rectangular waveguide 152 within the dielectric tube 154 to generate a plasma within the process volume 105, and purge the process chamber 110 with an inert gas upon completion of the cleaning process.

In some embodiments, the controller 190 configuration to clean the dielectric tube comprises instructions to provide a flow of cleaning gas, the cleaning gas further comprising a noble gas or molecular nitrogen (N₂), and the fluorine-containing compound and noble gas or molecular nitrogen are in a ratio in the range of 1:1 to 1:10, or in the range of 1:1 to 1:4, the fluorine-containing compound comprises one or more of carbon tetrafluoride (CF₄), nitrogen trifluoride (NF₃) or sulfur hexafluoride (SF₆); and a configuration to generate a continuous wave plasma with a power in the range of 2 kW to 12 kW, a pressure in the range of 0.1 Torr to 10 Torr, and maintaining a temperature in the range of room temperature to 300° C.

### Examples

Fused silica tubes were processed in a microwave plasma processing chamber using diborane (B₂H₆), nitrogen (N₂) and hydrogen (H₂) plasma chemistry over a period of about 80 hours. Samples were cleaned with a mixture of oxygen (O₂)/argon (90/10 sccm) at 6 kW continuous wave mode for a period of three hours at room temperature. Additional samples were cleaned using a mixture of carbon tetrafluoride (CF₄)/argon (20/40 sccm) at 6 kW continuous wave mode for two hours at room temperature. It was observed that the tubes cleaned using the oxygen/argon plasma showed little cleaning of the coating from the tube requiring replacement of the tubes. The carbon tetrafluoride/argon plasma exposure removed a significant amount of the coating, allowing an additional 80 hours of processing with the same tubes.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of cleaning a dielectric tube, the method comprising:
exposing the dielectric tube to a cleaning gas comprising a fluorine-containing compound; and
generating a microwave plasma from the cleaning gas to clean the dielectric tube.

2. The method of claim 1, wherein the cleaning gas further comprises a noble gas or molecular nitrogen (N₂).

3. The method of claim 2, wherein the fluorine-containing compound and noble gas or molecular nitrogen are in a ratio in the range of 1:1 to 1:10.

4. The method of claim 1, wherein the fluorine-containing compound comprises one or more of carbon tetrafluoride (CF₄), nitrogen trifluoride (NF₃) or sulfur hexafluoride (SF₆).

5. The method of claim 1, wherein the wherein microwave plasma is a continuous wave plasma.

6. The method of claim 5, wherein the microwave plasma has a power in the range of 2 kW to 12 kW.

7. The method of claim 5, wherein the cleaning gas is at a pressure in the range of 0.1 Torr to 10 Torr.

8. The method of claim 5, wherein the dielectric tube is maintained at a temperature in the range of room temperature to 300° C.

9. The method of claim 16, wherein the dielectric tube is cleaned in the same chamber as is used for plasma deposition processing resulting in the need for cleaning the dielectric tube, without removing the tube from a process position.

10. The method of claim 1, wherein the dielectric tube is a fused silica tube.

11. The method of claim 1, wherein the cleaned dielectric tube has at least double the lifetime of an uncleaned dielectric tube.

12. A method of depositing a film in a microwave plasma processing chamber, the method comprising:
depositing a film comprising carbon, boron, nitride or oxide on a substrate surface by exposing the substrate surface to a microwave plasma in the microwave plasma processing chamber, the microwave plasma generated using a microwave waveguide positioned within a dielectric tube, the film depositing on the substrate surface and the dielectric tube; and
cleaning the dielectric tube by exposing the dielectric tube to a cleaning microwave plasma of a cleaning gas, the cleaning gas comprising a fluorine-containing compound.

13. The method of claim 12, wherein there is more than one microwave waveguide in the microwave plasma processing chamber, each of the microwave waveguides positioned within a dielectric tube.

14. The method of claim 12, wherein depositing the film and cleaning the dielectric tube occur in the same microwave plasma processing chamber.

15. The method of claim 12, the cleaning gas further comprises a noble gas or molecular nitrogen (N₂), and the fluorine-containing compound and noble gas or molecular nitrogen are in a ratio in the range of 1:1 to 1:10.

16. The method of claim 17, wherein the fluorine-containing compound comprises one or more of carbon tetrafluoride (CF₄), nitrogen trifluoride (NF₃) or sulfur hexafluoride (SF₆).

17. The method of claim 12, wherein the cleaning microwave plasma is a continuous wave plasma with a power in the range of 2 kW to 12 kW, a pressure in the range of 0.1 Torr to 10 Torr, and maintained at a temperature in the range of room temperature to 300° C.

18. The method of claim 12, wherein the dielectric tube is a fused silica tube.

19. A microwave plasma processing chamber comprising:
at least one microwave plasma source comprising a microwave antenna within a dielectric tube comprising fused silica; and
a controller connected to the microwave plasma processing chamber, the controller having a configuration to deposit a film on a substrate surface within the microwave plasma processing chamber, and a configuration to clean the dielectric tube within the microwave plasma processing chamber, wherein cleaning the microwave plasma comprises exposing the dielectric tube to a cleaning microwave plasma of a cleaning gas, the cleaning gas comprising a fluorine-containing compound.

20. The microwave plasma processing chamber of claim 19, wherein the configuration to clean the dielectric tube comprises:
providing a flow of the cleaning gas, the cleaning gas further comprising a noble gas or molecular nitrogen (N₂), and the fluorine-containing compound and noble gas or molecular nitrogen are in a ratio in the range of 1:1 to 1:10, the fluorine-containing compound comprises one or more of carbon tetrafluoride (CF₄), nitrogen trifluoride (NF₃) or sulfur hexafluoride (SF₆); and
generating a continuous wave plasma with a power in the range of 2 kW to 12 kW, a pressure in the range of 0.1 Torr to 10 Torr, and maintaining a temperature in the range of room temperature to 300° C.
